(19) United States
(12) Patent Application Publication
(10) Pub. No.: US 2026/0190655 A1
(43) Pub. Date: Jul. 2, 2026

(54) DISPLAY DEVICE

(71) Applicant: LG DISPLAY CO., LTD., Seoul (KR)

(72) Inventors: Yoonhwan WOO, Seoul (KR); Jungwoo HAN, Cheongju-si (KR)

(73) Assignee: LG DISPLAY CO., LTD., Seoul (KR)

(21) Appl. No.: 19/204,272

(22) Filed: May 9, 2025

(30) Foreign Application Priority Data
Dec. 31, 2024 (KR) 10-2024-0202525

(51) Int. Cl. H10K 59/124; H10K 59/12; H10K 59/131

(52) U.S. Cl. CPC H10K 59/124; H10K 59/1201; H10K 59/131

(57) ABSTRACT

A display device includes: a substrate including a link area adjacent to a display area, and a bendable area adjacent to the link area; a signal line on the link area; a connection line on and connected to the signal line to extend from the link area to the bendable area; a planarization layer on the connection line; a stress relaxation layer on the planarization layer; at least one inorganic insulating layer on the planarization layer and the stress relaxation layer; and an organic protective layer on the inorganic insulating layer and the stress relaxation layer and covering an end of the inorganic insulating layer. A first groove is in an upper portion of the stress relaxation layer and adjacent to an end of the inorganic insulating layer. The organic protective layer is in the first groove to contact the stress relaxation layer.

### CROSS-REFERENCE TO RELATED APPLICATION

This application claims priority from Korean Patent Application No. 10-2024-0202525 filed on Dec. 31, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Discussion of the Related Art

Display devices are applied to various electronic devices such as TV, mobile phones, laptops, and tablets.

The display device includes an organic light-emitting display device (OLED) that emits light by itself, and a liquid crystal display device (LCD) that requires a separate light source.

A bezel area of the display device is recognized by the user and becomes a factor that degrades aesthetics and immersion. Recently, a display device of a narrow bezel in which a bezel area in which an image of the display device is not displayed is reduced has been in the spotlight.

### SUMMARY

Recently, as a flexible substrate is applied to a display panel, research and development are underway to reduce a bezel area of a display device as perceived by a user by bending a bendable area of a non-display area of the display panel and thus hiding a pad area of the non-display area under the display area.

In order to transmit various signals to pixels of the display area, connection lines extend along the bendable area, and the connection lines then are connected to signal lines in a link area adjacent to the display area.

An organic insulating layer and an inorganic insulating layer may be disposed on the connection lines, and the inorganic insulating layer may be lifted off from the organic insulating layer to form a gap between the inorganic insulating layer and the organic insulating layer, and moisture may flow into the connection lines through the gap, thereby causing corrosion and cracks of the connection lines. In addition, residual components of the developer used in the process for patterning the organic insulating layer together with moisture may be introduced into the connection lines, thereby promoting corrosion and cracking of the connection lines.

Accordingly, embodiments of the present disclosure are directed to a display device that substantially obviates one or more of the problems due to limitations and disadvantages of the related art.

An aspect of the present disclosure is to provide a display device capable of preventing an inorganic insulating layer disposed on connection lines of a display panel from being lifted off and preventing a residual component of a developer for patterning an organic insulating layer from flowing into the connection lines.

An aspect of the present disclosure is to provide a display device capable of reducing production energy required for production of the display device and reducing greenhouse gas emission resulting from the production.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a display area in which a plurality of light-emitting elements are disposed, a link area adjacent to the display area, and a bendable area adjacent to the link area; a signal line disposed on the link area so as to transmit a signal to the display area; a connection line disposed on the signal line and connected to the signal line, wherein the connection line extends from the link area to the bendable area; a planarization layer disposed on the connection line; a stress relaxation layer disposed on a partial area of the planarization layer; at least one inorganic insulating layer disposed on the planarization layer and the partial area of the stress relaxation layer; and an organic protective layer disposed on the at least one inorganic insulating layer and the stress relaxation layer and covering an end of the at least one inorganic insulating layer, wherein a first groove is defined in an upper portion of the stress relaxation layer and is adjacent to an end of the at least one inorganic insulating layer, wherein the organic protective layer is in contact with the stress relaxation layer in the first groove.

In another aspect, a method for manufacturing a display device comprises providing a substrate including a display area in which a plurality of light-emitting elements are disposed, a link area adjacent to the display area, and a bendable area adjacent to the link area; forming a signal line on the link area of the substrate; forming a connection line on the signal line so as to extend from the link area of the substrate to the bendable area thereof; forming a planarization layer on the connection line; forming a stress relaxation layer on a partial area of the planarization layer; forming at least one inorganic insulating layer so as to cover the planarization layer and the stress relaxation layer; forming a first opening extending through the at least one inorganic insulating layer and a first groove vertically overlapping the first opening in an upper portion of the stress relaxation layer; forming an organic protective layer so as to cover a portion of the at least one inorganic insulating layer on the link area, wherein an end of the organic protective layer is located in the first groove; and removing a portion of the at least one inorganic insulating layer not covered with the organic protective layer.

In another aspect, a display device comprises a substrate including a display area in which a plurality of light-emitting elements are disposed, a link area adjacent to the display area, and a bendable area adjacent to the link area; a signal line disposed on the link area so as to transmit a signal to the display area; a connection line disposed on the signal line and connected to the signal line, wherein the connection line extends from the link area to the bendable area; a planarization layer disposed on the connection line; at least one inorganic insulating layer disposed on a partial area of the planarization layer; and an organic protective layer disposed on the at least one inorganic insulating layer so as to cover an end of the at least one inorganic insulating layer, wherein a groove is defined in an upper portion of the planarization layer and is adjacent to an end of the at least one inorganic insulating layer, wherein the organic protective layer is in contact with the planarization layer in the groove.

According to embodiments of the present disclosure, the touch protective layer covers an end of the touch insulating layer disposed on a partial area of the stress relaxation layer disposed on the connection line. Further, the touch protective layer and the stress relaxation layer, which are respectively organic material layers, are in contact with each other in the groove defined in the upper portion of the stress relaxation layer. Thus, an adhesive force between the touch protective layer and the stress relaxation layer is improved, thereby preventing the touch insulating layer and the touch buffer layer from being lifted-off from the stress relaxation layer. Accordingly, moisture may be prevented from flowing toward the connection lines through the gap between the touch buffer layer and the stress relief layer.

In addition, according to embodiments of the present disclosure, after the touch protective layer is patterned in the photolithography process so as to be removed from the bendable area, a portion of each of the touch insulating layer and the touch buffer layer of the bendable area are removed, thereby preventing a residual component of the developer used in the process of patterning the touch protective layer from flowing into the connection lines.

According to the present embodiment, the touch protective layer covers the end of the touch insulating layer disposed on a partial area of the planarization layer disposed on the connection line. Further, the touch protective layer as an organic material layer and the planarization layer as an organic material layer contact each other in the groove of the planarization layer. Thus, the adhesion between the touch protective layer and the planarization layer is improved, thereby preventing the touch insulating layer and the touch buffer layer from being lifted-off from the planarization layer, and preventing moisture from flowing toward the connection lines through the gap between the touch buffer layer and the planarization layer.

Therefore, according to embodiments of the present disclosure, corrosion or cracking of the connection lines of the display panel may be prevented.

In addition, according to embodiments of the present disclosure, the lift-off of the inorganic insulating layer disposed on the connection lines of the display panel may be prevented using the existing process without adding a new mask and process. Further, the inflow of the remaining component of the developer for patterning the organic insulating layer into the connection lines may be prevented.

According to the embodiments of the present disclosure, a defect rate of the display device due to corrosion and cracks of the connection lines may be lowered, so that production energy required for production of the display device may be reduced and greenhouse gas emission for the production may be reduced.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a display device according to an embodiment of the present disclosure.

FIG. 2 is a cross-sectional view taken along a line II-II of FIG. 1.

FIG. 3 is an enlarged view of an area A of FIG. 1.

FIG. 4 is a cross-sectional view taken along a line IV-IV of FIG. 3.

FIG. 5 is a cross-sectional view of a display device according to an embodiment of the present disclosure, and a cross-sectional view corresponding to FIG. 4.

FIG. 6 is a plan view of a display device according to an embodiment of the present disclosure, and is a plan view corresponding to FIG. 3.

FIG. 7 is a cross-sectional view taken along a line VI-VI of FIG. 6.

FIGS. 8 and 9 are plan views of a display device according to embodiments of the present disclosure, and are plan views corresponding to FIG. 3.

FIGS. 10 to 13 are cross-sectional views illustrating a method for manufacturing a display device according to an embodiment of the present disclosure.

FIG. 14 is a cross-sectional view of a display device according to an embodiment of the present disclosure.

FIG. 15 is a cross-sectional view of a display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’or ‘directly transferred’is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. In this regard, a scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

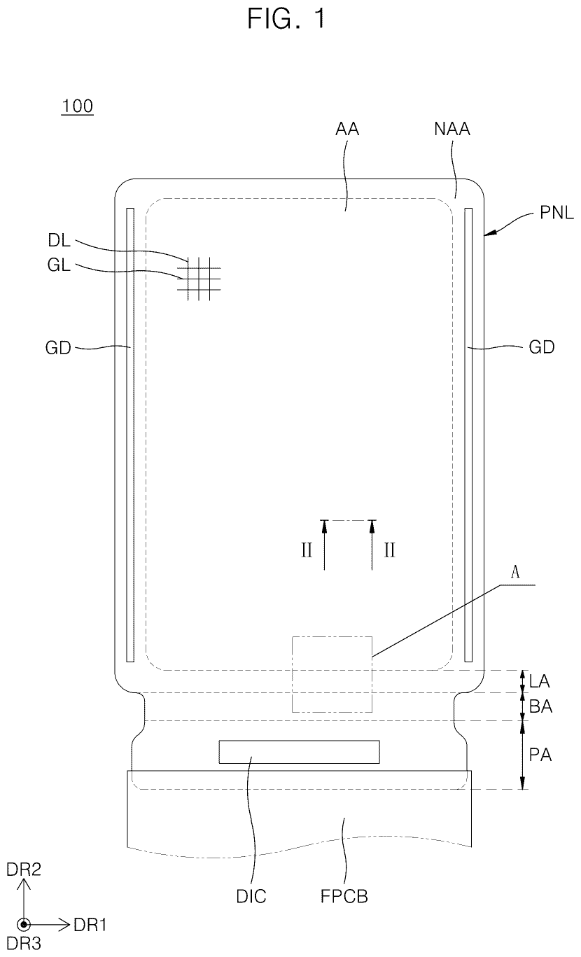

FIG. 1 is a plan view of a display device according to an embodiment of the present disclosure.

Referring to FIG. 1, a display device 100 according to an embodiment of the present disclosure may include a display panel PNL, a data driver DIC, a flexible printed circuit board FPCB, etc.

The display panel PNL includes a display area AA and a non-display area NAA. The display area AA and the non-display area NAA may be areas of a substrate in the display panel PNL. The display area AA is an area in which an image is displayed. The non-display area NAA is an area which is located outside the display area AA and in which the image is not displayed.

The display area AA is an area in which a plurality of pixels are arranged. Each pixel may include a plurality of sub-pixels. The non-display area NAA is an area in which a gate driver GD and various lines are disposed.

The display area AA includes a plurality of data lines DL and a plurality of gate lines GL extending so as to intersect each other. The plurality of gate lines GL may extend, for example, in a first direction DR1, and the plurality of data lines DL may extend, for example, in a second direction DR2. The data line DL transmits a data signal generated by the data driver DIC to the sub-pixel, and the gate line GL transmits the gate signal generated by the gate driver GD to the sub-pixel.

For example, the gate driver GD may be disposed in the non-display area NAA and in a portion disposed on each of the left and right sides of the display area AA. The gate driver GD may be formed directly on the substrate of the display panel PNL and thus may be implemented in a GIP (gate driver in panel) manner.

The non-display area NAA may be disposed to surround the display area AA. The non-display area NAA may be disposed on an upper side, a lower side, a left side, and a right side of the display area AA. A portion of the non-display area NAA disposed on the lower side of the display area AA includes a pad area PA to which the data driver DIC and the flexible printed circuit board FPCB are bonded, and a link area LA and a bendable area BA defined between the display area AA and the pad area PA.

The data driver DIC and the flexible printed circuit board FPCB may be bonded to the pad area PA via an anisotropic conductive film. A timing controller, a power supply, etc. may be mounted on the flexible printed circuit board FPCB.

In an embodiment, the data driver DIC may be mounted on the flexible printed circuit board FPCB. A printed circuit board on which the timing controller, the power supply, etc. are mounted may be connected to the flexible printed circuit board FPCB.

The bendable area BA of the non-display area NAA of the display panel PNL may be bent at a predetermined curvature. As the bendable area BA of the display panel PNL is bent, the pad area PA of the non-display area NAA may be located under the display area AA. Accordingly, the bezel area in a lower side of the display device as recognized from a viewer in front of the display device may be reduced.

The data lines DL may be connected to the data driver DIC via a connection line. The data line DL may be connected to the connection line in the link area LA. The connection line may extend from the link area LA across the bendable area BA to the pad area PA.

The data lines DL may be connected to the data driver DIC via a data link line and the connection line. The data line DL may be connected to the connection line via a contact hole defined in the link area LA. The connection line may extend from the link area LA across the bendable area BA to the pad area PA.

The gate driver GD may be connected to the flexible printed circuit board FPCB via a gate routing line and the connection line.

A touch sensor may be disposed in the display area AA. The touch sensor may include a first touch electrode line extending in the first direction DR1 and a second touch electrode line extending in the second direction DR2. The first touch electrode line and the second touch electrode line may be connected to the flexible printed circuit board FPCB via a touch routing line and the connection line disposed in the non-display area NAA.

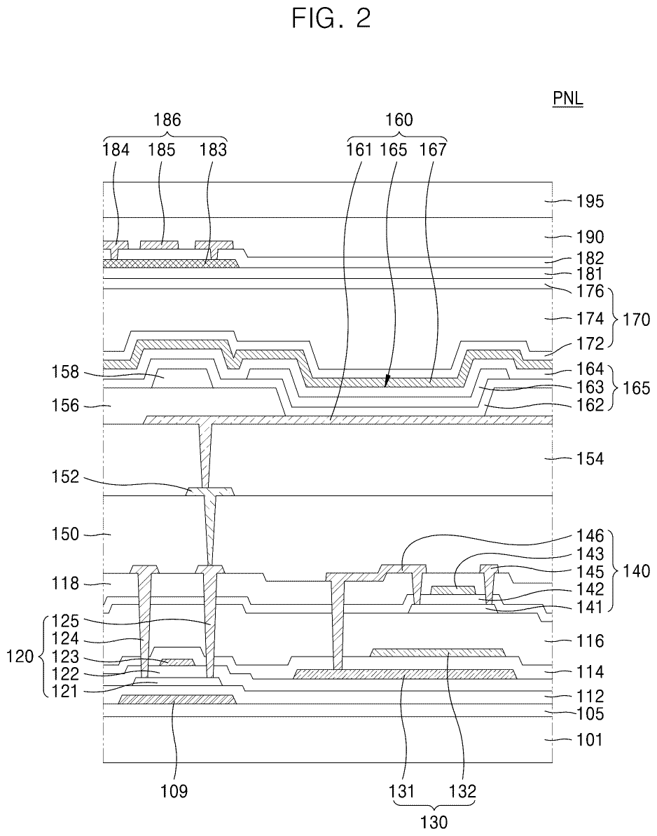

FIG. 2 is a cross-sectional view taken along a line II-II of FIG. 1. FIG. 2 schematically illustrates a display panel of a display device according to an embodiment of the present disclosure.

Referring to FIG. 2, the display panel PNL of the display device according to the embodiment of the present disclosure may include a substrate 101, a first thin-film transistor 120, a storage capacitor 130, a second thin-film transistor 140, a light-emitting element 160, and a touch sensor 186.

The substrate 101 may include an insulating material. The substrate 101 may include a polymer material having flexibility. The substrate 101 may have a multilayer structure. For example, the substrate 101 may include a lower substrate layer and an upper substrate layer made of a polymer material such as polyimide (PI), and an intermediate layer made of an inorganic insulating material and disposed between the lower substrate layer and the upper substrate layer.

A first buffer layer 105 may be disposed on the substrate 101. The first buffer layer 105 may be disposed in an entirety of the display area AA of the substrate 101. The first buffer layer 105 may include an insulating material. For example, the first buffer layer 105 may include an inorganic insulating material such as silicon oxide, silicon nitride, and silicon oxynitride. The first buffer layer 105 may have a multilayer structure.

A light blocking layer 109 may be disposed on the first buffer layer 105. The light blocking layer 109 may include a metal material. For example, the light blocking layer 109 may include a metal material such as aluminum (Al), chromium (Cr), copper (Cu), titanium (Ti), molybdenum (Mo), and tungsten (W).

A second buffer layer 112 may be disposed on the first buffer layer 105 so as to cover the light blocking layer 109. The second buffer layer 112 may include an insulating material. For example, the second buffer layer 112 may include an inorganic insulating material such as silicon oxide, silicon nitride, and silicon oxynitride. The second buffer layer 112 may have a multilayer structure.

A driving circuit DC may be located in each sub-pixel. The driving circuit DC may generate a driving current to be provided to the light-emitting element. The driving circuit DC may be electrically connected to the signal lines. For example, the signal lines may include a gate line GL for applying a gate signal, a data line DL for applying a data signal, and power supply lines for supplying a power voltage. For example, the driving circuit may include a first thin-film transistor 120, a second thin-film transistor 140, and a storage capacitor 130.

The first thin-film transistor 120 may be electrically connected to the light-emitting element 160. The first thin-film transistor 120 may include a first semiconductor pattern 121, a first gate insulating layer 122, a first gate electrode 123, a first source electrode 124, and a first drain electrode 125. The first semiconductor pattern 121 may be disposed on the second buffer layer 112.

The first semiconductor pattern 121 may include a semiconductor material. For example, the first semiconductor pattern 121 may include a polycrystalline semiconductor material. For example, the first semiconductor pattern 121 may include low temperature poly-Si (LTPS).

The first gate insulating layer 122 may be disposed on the first semiconductor pattern 121. The first gate insulating layer 122 may extend outwardly of the first semiconductor pattern 121. For example, the first gate insulating layer 122 may extend along and on an upper surface of the second buffer layer 112. The first gate insulating layer 122 may include an insulating material. For example, the first gate insulating layer 122 may include an inorganic insulating material such as silicon oxide, silicon nitride, and silicon oxynitride.

The first gate electrode 123 may be disposed on the first gate insulating layer 122. The first gate electrode 123 may include a conductive material. For example, the first gate electrode 123 may include a metal material such as aluminum (Al), chromium (Cr), copper (Cu), titanium (Ti), molybdenum (Mo), and tungsten (W). The first gate electrode 123 may be electrically insulated from the first semiconductor pattern 121 via the first gate insulating layer 122. The first gate electrode 123 may vertically overlap a first channel area CH1 of the first semiconductor pattern 121.

A first interlayer insulating layer 114 may be disposed on the first gate electrode 123. The first interlayer insulating layer 114 may extend outwardly of the first gate electrode 123. The first interlayer insulating layer 114 may extend along and on an upper surface of the first gate insulating layer 122. The first interlayer insulating layer 114 may include an insulating material. For example, the first interlayer insulating layer 114 may include an inorganic insulating material such as silicon oxide, silicon nitride, and silicon oxynitride.

A first source electrode 124 and a first drain electrode 125 may be electrically connected to the first semiconductor pattern 121.

The storage capacitor 130 may include a first storage electrode 131 and a second storage electrode 132. For example, the first storage electrode 131 may be disposed in the same layer as a layer of the first gate electrode 123. For example, the first storage electrode 131 may be made of the same material as that of the first gate electrode 123. The first storage electrode 131 may be disposed adjacent to the first gate electrode 123 while being disposed on the gate insulating layer 122. The second storage electrode 132 may be disposed on the first interlayer insulating layer 114 so as to vertically overlap the first storage electrode 131.

Each of the first storage electrode 131 and the second storage electrode 132 may include a conductive material. For example, each of the first storage electrode 131 and the second storage electrode 132 may include a metal material such as aluminum (Al), chromium (Cr), copper (Cu), titanium (Ti), molybdenum (Mo), and tungsten (W).

An isolation insulating layer 116 may be disposed on the first interlayer insulating layer 114 so as to cover the second storage electrode 132. The isolation insulating layer 116 may include an insulating material. For example, the isolation insulating layer 116 may include an inorganic insulating material such as silicon oxide, silicon nitride, and silicon oxynitride. For example, the isolation insulating layer 116 may have a multilayer structure including a first layer made of silicon oxide and a second layer made of silicon nitride.

The second thin-film transistor 140 may be electrically connected to the first thin-film transistor 120. For example, the second thin-film transistor 140 may include a second semiconductor pattern 141, a second gate insulating layer 142, a second gate electrode 143, a second source electrode 145, and a second drain electrode 146.

The second semiconductor pattern 141 may include a semiconductor material. The second semiconductor pattern 141 may include a material different from that of the first semiconductor pattern 121. For example, the second semiconductor pattern 141 may include an oxide semiconductor such as IGZO. The second semiconductor pattern 141 may be disposed in a different layer from a layer of the first semiconductor pattern 121. The second semiconductor pattern 141 may be disposed on the isolation insulating layer 116. Accordingly, damage to the second semiconductor pattern 141 due to the process of forming the first semiconductor pattern 121 may be prevented.

The second gate insulating layer 142 may be disposed on the second semiconductor pattern 141. The second gate insulating layer 142 may extend outwardly of the second semiconductor pattern 141. For example, the second gate insulating layer 142 may extend along and on an upper surface of the isolation insulating layer 116. The second gate insulating layer 142 may include an insulating material. The second gate insulating layer 142 may include an inorganic insulating material such as silicon oxide, silicon nitride, and silicon oxynitride.

The second gate electrode 143 may be disposed on the second gate insulating layer 142. For example, the second gate electrode 143 may vertically overlap a second channel area CH2 of the second semiconductor pattern 141. The second gate electrode 143 may include a conductive material. For example, the second gate electrode 143 may include a metal material such as aluminum (Al), chromium (Cr), copper (Cu), titanium (Ti), molybdenum (Mo), and tungsten (W). For example, the second gate electrode 143 may be made of the same material as that of the first gate electrode 123. The second gate electrode 143 may be electrically insulated from the second semiconductor pattern 141 via the second gate insulating layer 142.

A second interlayer insulating layer 118 may be disposed on the second gate electrode 143. The second interlayer insulating layer 118 may extend outwardly of the second gate electrode 143. The second interlayer insulating layer 118 may extend along and on the upper surface of the isolation insulating layer 116. The second interlayer insulating layer 118 may include an insulating material. For example, the second interlayer insulating layer 118 may include an inorganic insulating material such as silicon oxide, silicon nitride, and silicon oxynitride. For example, the second interlayer insulating layer 118 may have a multilayer structure including a first layer made of silicon oxide and a second layer made of silicon nitride.

The first source electrode 124, the first drain electrode 125, a second source electrode 145, and a second drain electrode 146 may be disposed on the second interlayer insulating layer 118. Each of the first source electrode 124, the first drain electrode 125, the second source electrode 145, and the second drain electrode 146 may include a conductive material. For example, each of the first source electrode 124, the first drain electrode 125, the second source electrode 145, and the second drain electrode 146 may include a metal material such as aluminum (Al), chromium (Cr), copper (Cu), titanium (Ti), molybdenum (Mo), and tungsten (W). For example, each of the first source electrode 124, the first drain electrode 125, the second source electrode 145, and the second drain electrode 146 may have a multi-layered structure of a titanium (Ti) layer/aluminum (Al) layer/titanium (Ti) layer.

The first source electrode 124 and the first drain electrode 125 may be electrically connected to the first semiconductor pattern 121. For example, the first source electrode 124 and the first drain electrode 125 may be in direct contact with the first semiconductor pattern 121 via respective contact holes extending through the second interlayer insulating layer 118, the second gate insulating layer 142, the isolation insulating layer 116, the first interlayer insulating layer 114, and the first gate insulating layer 122.

The second source electrode 145 and the second drain electrode 146 may be electrically connected to the second semiconductor pattern 141. For example, the second source electrode 145 and the second drain electrode 146 may be in direct contact with the second semiconductor pattern 141 via respective contact holes extending through the second interlayer insulating layer 118 and the second gate insulating layer 142.

The second thin-film transistor 140 may be disposed on the storage capacitor 130. For example, the second semiconductor pattern 141 of the second thin-film transistor 140 may vertically overlap the storage capacitor 130. Light traveling through the substrate 101 toward the second semiconductor pattern 141 may be blocked by the storage capacitor 130. Accordingly, a change in characteristics of the second thin-film transistor 140 due to external light may be prevented. The storage capacitor 130 may be electrically connected to the second drain electrode 146 of the second thin-film transistor 140. For example, the second drain electrode 146 may be in direct contact with the first storage electrode 131 via a contact hole extending through the second interlayer insulating layer 118, the second gate insulating layer 142, the isolation insulating layer 116, and the first interlayer insulating layer 114.

The light-emitting element 160 may be disposed on the driving circuit DC. For example, the first thin-film transistor 120, the second thin-film transistor 140, and the storage capacitor 130 of each sub-pixel may be positioned between the substrate 101 and the light-emitting element 160.

A first planarization layer 150 and a second planarization layer 154 may be sequentially stacked while being disposed between the driving circuit DC and the light-emitting element 160. The first planarization layer 150 and the second planarization layer 154 may provide a flat upper surface by covering a step caused by the driving circuit. For example, each of the first planarization layer 150 and the second planarization layer 154 may include an organic insulating material.

A pixel contact electrode 152 may be disposed on the first planarization layer 150. The light-emitting element 160 may be disposed on the second planarization layer 154. The light-emitting element 160 may include a first electrode 161, a light-emitting layer 165, and a second electrode 167. The light-emitting element 160 may be electrically connected to the first drain electrode 125 of the first thin-film transistor 120 via the pixel contact electrode 152. The pixel contact electrode 152 may include a conductive material. For example, the pixel contact electrode 152 may include a metal material such as aluminum (Al), chromium (Cr), copper (Cu), titanium (Ti), molybdenum (Mo), and tungsten (W). For example, the pixel contact electrode 152 may have a multilayer structure of titanium (Ti) layer/aluminum (Al) layer/titanium (Ti) layer.

A bank layer 156 may be disposed on the second planarization layer 154. The bank layer 156 may include an organic insulating material. For example, the bank layer 156 may be made of a photosensitive acrylic-based or polyimide-based organic material. The bank layer 156 may cover an edge of the first electrode 161. The bank layer 156 may have an opening defined therein exposing a partial area of the first electrode 161. The light-emitting layer 165 and the second electrode 167 of the light-emitting element 160 may be stacked on the partial area of the first electrode 161 not covered with the bank layer 156. A light emission area may be defined by the partial area of the first electrode 161 exposed through the opening of the bank layer 156. The first electrode 161 may include a conductive material. The first electrode 161 may have a high reflectance. For example, the first electrode 161 may include a metal material such as aluminum (Al) and silver (Ag). The first electrode 161 may have a multi-layered structure. For example, the first electrode 161 may have a structure in which a metal layer made of aluminum (Al) and silver (Ag) is disposed between layer made of transparent conductive materials such as ITO and IZO.

The light-emitting layer 165 may extend onto the bank layer 156. The light-emitting layer 165 may include a light-emitting material layer 163. For example, the light-emitting material layer 163 may include an organic light-emitting material. The light-emitting layer 165 may have a multilayer structure. For example, the light-emitting layer 165 may include at least one of a first light-emitting common layer 162 disposed between the first electrode 161 and the light-emitting material layer 163 and a second light-emitting common layer 164 disposed between the light-emitting material layer 163 and the second electrode 167. For example, the first light-emitting common layer 162 may include at least one of a Hole Injection Layer (HIL) and a Hole Transport Layer (HTL). The second light-emitting common layer 164 may include at least one of an Electron Transport Layer (ETL) and an Electron Injection Layer (EIL).

For example, when the sub-pixels of each pixel are designed to emit light of different colors, the light-emitting material layer 163 of each sub-pixel may be isolated from the light-emitting material layer 163 of an adjacent sub-pixel thereto. The light-emitting material layer 163 of each sub-pixel may be separately formed using a Fine Metal Mask (FMM). An end of the light-emitting material layer 163 may be disposed on the bank layer 156.

For example, a spacer 158 may be disposed on the bank layer 156. The spacer 158 may prevent the bank layer 156 and the light-emitting material layer 163 from being damaged by the contact of the fine metal mask. For example, the spacer 158 may be made of a photosensitive acrylic-based or polyimide-based organic material. The bank layer 156 and the spacer 158 may be simultaneously formed in one photolithography process. However, embodiments of the present disclosure are not limited thereto. The bank layer 156 and the spacer 158 may be formed in separate processes.

The first light-emitting common layer 162 and the second light-emitting common layer 164 of the light-emitting layer 165 may extend along and on the surface of the bank layer 156. The first light-emitting common layer 162 and the second light-emitting common layer 164 of the light-emitting layer 165 may cover the upper surface and the side surfaces of the spacer 158. For example, each of the first light-emitting common layer 162 and the second light-emitting common layer 164 may be commonly disposed in adjacent sub-pixels. For example, each of the first light-emitting common layer 162 and the second light-emitting common layer 164 may be commonly disposed across all pixels of the display area AA.

The second electrode 167 may be commonly disposed in adjacent sub-pixels. For example, the second electrode 167 may be commonly disposed in all pixels of the display area AA. The second electrode 167 may include a conductive material. For example, the second electrode 167 may be a transparent electrode made of a transparent conductive material such as ITO and IZO.

An encapsulation area 170 may be disposed on the light-emitting element 160. The encapsulation area 170 may prevent damage to the light-emitting elements 160 due to external impact and moisture. The encapsulation area 170 may have a multi-layer structure. For example, the encapsulation area 170 may include a first encapsulation layer 172, a second encapsulation layer 174, and a third encapsulation layer 176, which are sequentially stacked. For example, each of the first encapsulation layer 172 and the third encapsulation layer 176 may include an inorganic insulating material, and the second encapsulation layer 174 may include an organic insulating material.

The encapsulation area 170 may extend outwardly of the display area AA. At least one dam structure may be disposed in the non-display area NAA. For example, the dam structure may be disposed on the first planarization layer 150. For example, the dam structure may include at least one organic insulating material. For example, the dam structure may include a first layer made of the same material as that of the second planarization layer 154 and a second layer made of the same material as that of the bank layer 156. The dam structure may have a closed loop shape surrounding the display area AA of the substrate 101. Since the flow of the second encapsulation layer 174 having fluidity may be blocked by the dam structure, the second encapsulation layer 174 may be disposed only in a partial area of the substrate 101 defined by the dam structure. The third encapsulation layer 176 may be in direct contact with the first encapsulation layer 172 in an area outside the second encapsulation layer 174.

The touch sensor 186 may be disposed on the encapsulation area 170. The touch sensor 186 may include a bridge electrode 183, a first touch electrode 184, and a second touch electrode 185. The bridge electrode 183, the first touch electrode 184, and the second touch electrode 185 may be positioned so as to vertically overlap the bank layer 156. The light emitted from each light-emitting element 160 may not be blocked by the bridge electrode 183, the first touch electrode 184, and the second touch electrode 185.

A touch buffer layer 181 may be disposed between the encapsulation area 170 and the touch sensor 186. The touch buffer layer 181 may prevent the encapsulation area 170 and the light-emitting element 160 from being damaged in a process of forming the first touch electrode 184, the bridge electrode 183, and the second touch electrode 185. For example, an upper surface of the encapsulation area 170 may be covered with the touch buffer layer 181. For example, the touch buffer layer 181 may extend to the non-display area NAA. The touch buffer layer 181 may include an insulating material. For example, the touch buffer layer 181 may include an inorganic insulating material such as silicon oxide, silicon nitride, and silicon oxynitride. The touch buffer layer 181 may be a first inorganic insulating layer.

The bridge electrode 183 may be disposed on the touch buffer layer 181. The touch insulating layer 182 may be disposed on the bridge electrode 183. The touch insulating layer 182 may extend along and on the upper surface of the touch buffer layer 181. For example, the touch insulating layer 182 may extend to the non-display area NAA. For example, the touch insulating layer 182 may include an inorganic insulating material such as silicon oxide, silicon nitride, and silicon oxynitride. The touch insulating layer 182 may be a second inorganic insulating layer.

The first touch electrodes 184 and the second touch electrodes 185 may be disposed on the touch insulating layer 182. The bridge electrode 183 may electrically connect adjacent first touch electrodes 184 to each other. The adjacent first touch electrodes 184 may be connected to the bridge electrode 183 via respective contact holes extending through the touch insulating layer 182. The bridge electrode 183 and the first touch electrode 184 may constitute a first touch electrode line. The second touch electrode 185 may form a second touch electrode line.

Each of the bridge electrode 183, the first touch electrode 184, and the second touch electrode 185 may include a conductive material. For example, the bridge electrode 183, the first touch electrode 184, and the second touch electrode 185 may include a metal material such as aluminum (Al), chromium (Cr), copper (Cu), titanium (Ti), molybdenum (Mo), and tungsten (W). For example, each of the bridge electrode 183, the first touch electrode 184, and the second touch electrode 185 may have a multi-layered structure of titanium (Ti) layer/aluminum (Al) layer/titanium (Ti) layer.

A touch protective layer 190 may be disposed on the touch sensor layer 186. The touch protective layer 190 may prevent damage to the touch sensor layer 186 due to external impact and moisture. The touch protective layer 190 may include an insulating material. For example, the touch protective layer 190 may include an organic insulating material. For example, the touch protective layer 190 may be made of a photosensitive acrylic-based or polyimide-based organic material. The touch protective layer 190 may be an organic protective layer. The touch protective layer 190 may extend to the non-display area NAA.

A cover layer 195 may be disposed on the touch protective layer 190. For example, the cover layer 195 may include an organic insulating material. For example, the cover layer 195 may be made of an acrylic-based, polyimide-based, epoxy-based, or silane-based resin. The touch protective layer 190 may extend to the non-display area NAA. The cover layer 195 may extend to the non-display area NAA. In an embodiment, the cover layer 195 may be omitted.

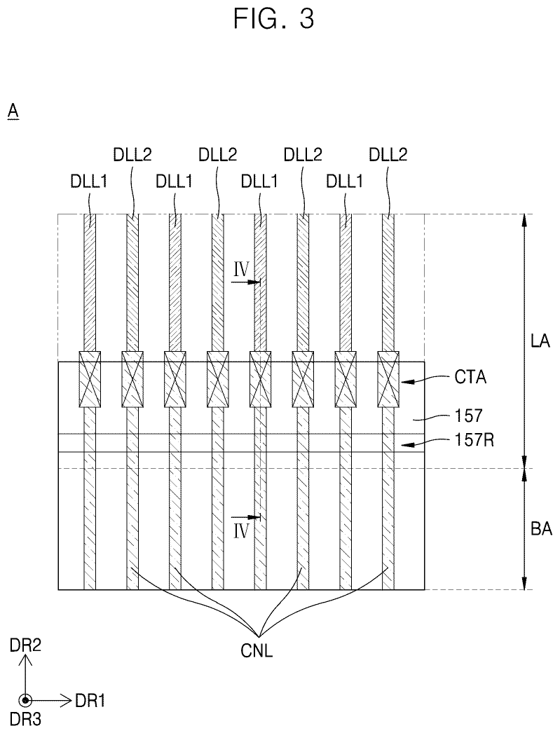

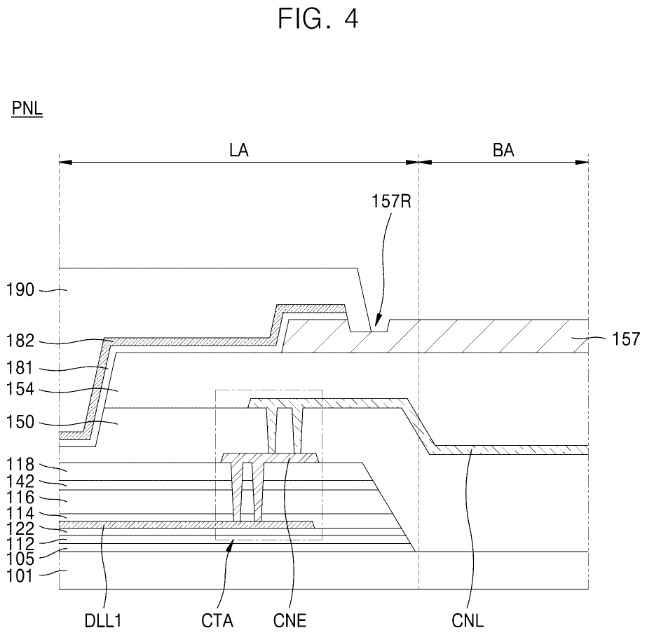

FIG. 3 is an enlarged view of an area A of FIG. 1. FIG. 4 is a cross-sectional view taken along a line IV-IV of FIG. 3. FIG. 3 is a plan view illustrating a portion of the non-display area NAA of the display panel PNL.

Referring to FIG. 3, data link lines DLL1 and DLL2 may extend, for example, in the second direction, and may be disposed in the link area LA. The data link lines DLL1 and DLL2 may be connected to connection lines CNL in a contact area CTA located in the link area LA, respectively. The connection lines CNL may be disposed on the data link lines DLL1 and DLL2. A portion of each of the connection lines CNL may vertically overlap each of the data link lines DLL1 and DLL2. For example, each of the connection lines CNL may extend from the link area LA to the bendable area BA in the second direction. The connection lines CNL may extend across the bendable area BA to the pad area PA. The data link lines DLL1 and DLL2 may include the first data link line DLL1 and the second data link line DLL2 which may be disposed in different layers. The present disclosure is not limited to an example in which the data link lines are disposed in two different layers. The data link lines may be disposed in three or more different layers.

A stress relaxation layer 157 may be disposed on the connection lines CNL so as to vertically overlap the connection lines CNL. The stress relaxation layer 157 may be disposed on the data link lines DLL1 and DLL2 so as to vertically overlap the ends of the data link lines DLL1 and DLL2. The stress relaxation layer 157 may be disposed in a partial area of the link area LA and an entire area of the bendable area BA.

The stress relaxation layer 157 may include a groove 157R defined therein and extending in a direction (e.g., the first direction) so as to intersect the connection lines CNL. The groove 157R may extend in a linear shape, for example. The groove 157R may extend over an entirety of the bendable area BA and extend in a direction (e.g., the first direction) so as to intersect the connection lines CNL. The groove 157R may be disposed in the link area LA. However, embodiments of the present disclosure are not limited thereto. In an embodiment, the groove 157R may be disposed in the bendable area BA.

Referring to FIG. 4, the first buffer layer 105, the second buffer layer 112, the first gate insulating layer 122, the first interlayer insulating layer 114, the isolation insulating layer 116, the second gate insulating layer 142, and the second interlayer insulating layer 118 may be sequentially stacked on the link area LA of the substrate 101.

However, the first buffer layer 105, the second buffer layer 112, the first gate insulating layer 122, the first interlayer insulating layer 114, the isolation insulating layer 116, the second gate insulating layer 142, and the second interlayer insulating layer 118, which are made of an inorganic insulating material in which cracks are likely to occur, may not be disposed in the bendable area BA of the substrate 101. An end of each of the first buffer layer 105, the second buffer layer 112, the first gate insulating layer 122, the first interlayer insulating layer 114, the isolation insulating layer 116, the second gate insulating layer 142, and the second interlayer insulating layer 118 extending from the display area AA may be disposed in the link area LA. For example, the end of the first buffer layer 105 disposed on the upper surface of the substrate 101 may define a boundary between the link area LA and the bendable area BA of the substrate 101.

The first data link line DLL1 may be disposed on the link area LA of the substrate 101. Although not shown in FIG. 4, the second data link line DLL2 may also be disposed on the link area LA of the substrate 101. The first data link line DLL1 may be disposed, for example, between the first gate insulating layer 122 and the first interlayer insulating layer 114. The first data link line DLL1 may be made of the same material as that of the first gate electrode 123 and may be formed in the same process as a formation process of the first gate electrode 123. The second data link line DLL2 may be disposed, for example, between the first interlayer insulating layer 114 and the isolation insulating layer 116. The second data link line DLL2 may be made of the same material as that of the second storage electrode 132 and may be formed in the same process as a formation process of the second storage electrode 132.

In addition, the link contact electrode CNE may be disposed on the second interlayer insulating layer 118 and on the link area LA of the substrate 101. The link contact electrode CNE may be made of the same material as that of the second source electrode 145 and the second drain electrode 146 and may be formed in the same process as a formation process of the second source electrode 145 and the second drain electrode 146.

The first planarization layer 150 covering the link contact electrode CNE may be disposed on the second interlayer insulating layer 118. The first planarization layer 150 may be continuously disposed along and on the link area LA, the bendable area BA, and the pad area PA of the substrate 101. The first planarization layer 150 may be directly disposed on the bendable area BA of the substrate 101.

The connection line CNL may be disposed on the first planarization layer 150 and may be disposed on the link area LA and the bendable area BA of the substrate 101. The connection line CNL may be made of the same material as that of the pixel contact electrode 152 and may be formed in the same process as a formation process of pixel contact electrode 152. The connection line CNL may be disposed on the first planarization layer 150.

The connection line CNL may be connected to the link contact electrode CNE via a contact hole extending through the first planarization layer 150 in the contact area CTA. The link contact electrode CNE may be connected to the first data link line DLL1 via a contact hole extending through the first interlayer insulating layer 114, the isolation insulating layer 116, the second gate insulating layer 142, and the second interlayer insulating layer 118 in the contact area CTA. The connection line CNL may be connected to the first data link line DLL1 via the link contact electrode CNE. Although not shown in FIG. 4, the connection line CNL may be connected to the second data link line DLL2 via the link contact electrode CNE. The link contact electrodes CNE may be disposed in each contact area CTA, and neighboring link contact electrodes CNE may be insulated from each other.

The second planarization layer 154 covering the connection line CNL may be disposed on the first planarization layer 150. The second planarization layer 154 may be disposed in the link area LA and the bendable area BA of the substrate 101. The second planarization layer 154 may expose a portion of the first planarization layer 150 in the link area LA. The second planarization layer 154 may prevent damage to the connection line CNL due to external impact, moisture, or the like.

The stress relaxation layer 157, the touch buffer layer 181, and the touch insulating layer 182 may be disposed on the second planarization layer 154 and in the link area LA of the non-display area NAA. The stress relaxation layer 157 may expose the portion of the second planarization layer 154 in the link area LA. The stress relaxation layer 157 may cover the second planarization layer 154 in the bendable area BA. An upper portion of the stress relaxation layer 157 may include the groove 157R defined therein in the link area LA. The stress relaxation layer 157 may be made of the same material as that of the bank layer 156 of the display area AA. The stress relaxation layer 157 may be disposed to be spaced apart from the bank layer 156 of the display area AA. The groove 157R extending so as to intersect the connection lines CNL may be defined in the upper portion of the stress relaxation layer 157.

The touch buffer layer 181 and the touch insulating layer 182 may extend from the display area AA and may cover an upper surface of the second planarization layer 154 not covered with the stress relaxation layer 157 and a portion of an upper surface of the stress relaxation layer 157 in the link area LA. An end of the touch buffer layer 181 and an end of the touch insulating layer 182 may be aligned with each other. The groove 157R of the stress relaxation layer 157 may be adjacent to the end of the touch buffer layer 181 and the end of the touch insulating layer 182. A side surface of the end of the touch buffer layer 181 may be aligned with an inner side surface of the groove 157R of the stress relaxation layer 157. The inner side surface of the groove 157R of the stress relaxation layer 157 is a side surface closer to the display area AA among opposite side surfaces of the groove 157R of the stress relaxation layer 157, while an outer side surface of the groove 157R of the stress relaxation layer 157 is a side surface closer to the bendable area BA among the opposite side surfaces of the groove 157R of the stress relaxation layer 157.

The touch protective layer 190 may be disposed on the touch insulating layer 182 and the stress relaxation layer 157. The touch protective layer 190 may cover the end of the touch buffer layer 181 and the end of the touch insulating layer 182. The touch protective layer 190 may be in contact with the stress relaxation layer 157 in the groove 157R of the stress relaxation layer 157. An end of the touch protective layer 190 may be located in the groove 157R of the stress relaxation layer 157R. The touch protective layer 190 may fill a portion of the groove 157R of the stress relaxation layer 157.

In an embodiment, one of the touch buffer layer 181 or the touch insulating layer 182 may not be disposed in the link area LA and the bendable area BA.

According to the present embodiment, the touch protective layer covers the end of the touch insulating layer disposed on the partial area of the stress relaxation layer disposed on the connection line. The touch protective layer as an organic material layer and the stress relaxation layer as an organic material layer contact each other in the groove defined in the upper portion of the stress relaxation layer, so that the adhesive force between the touch protective layer and the stress relaxation layer is improved, thereby preventing the touch insulating layer and the touch buffer layer from being lifted off from the stress relaxation layer, and preventing moisture from flowing toward the connection lines through a gap between the touch buffer layer and the stress relaxation layer.

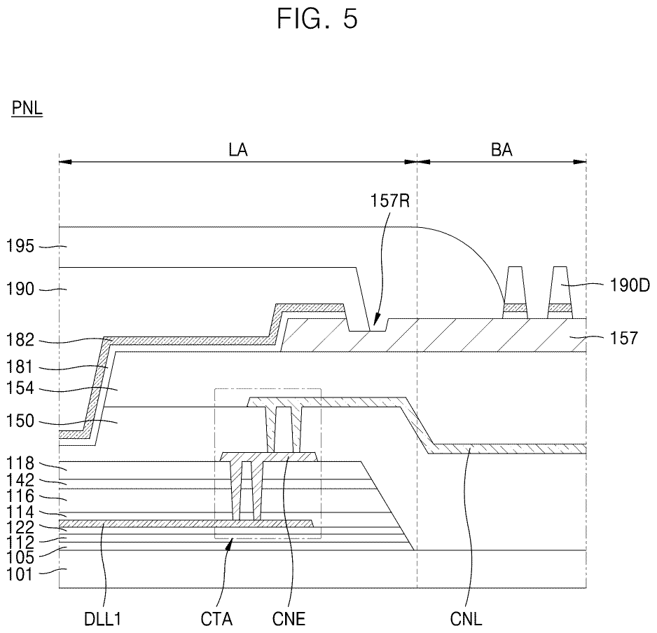

FIG. 5 is a cross-sectional view of a display device according to an embodiment of the present disclosure, and a cross-sectional view corresponding to FIG. 4.

Referring to FIG. 5, the display panel PNL of the display device according to an embodiment of the present disclosure may further include a plurality of partition walls 190D disposed on a partial area of the stress relaxation layer 157 and the cover layer 195 disposed on the touch protective layer 190.

The plurality of partition walls 190D may be disposed in the bendable area BA. However, embodiments of the present disclosure are not limited thereto. The plurality of partition walls 190D may serve as a dam that restricts the flow of an organic material constituting the cover layer 195 in the process of forming the cover layer 195 disposed on the touch protective layer 190. Each partition wall 190D may extend in a closed loop shape surrounding the display area AA of the substrate 101 and may be disposed in the non-display area NAA. Each of the plurality of partition walls 190D may be made of the same material as that of the touch protective layer 190 and may be formed in the same process as a formation process of the touch protective layer 190.

A portion of each of the touch buffer layer 181 and the touch insulating layer 182 may be disposed between each partition wall 190D and the stress relaxation layer 157. The portion of each of the touch buffer layer 181 and the touch insulating layer 182 disposed under the partition wall 190D may extend so as to have a closed loop shape in the same manner as the partition wall 190D.

The cover layer 195 may be disposed in the link area LA and the bendable area BA of the display panel PNL. The cover layer 195 may cover an end of the touch protective layer 190. The cover layer 195 may be in contact with a portion of the stress relaxation layer 157 located between the end of the touch protective layer 190 and the partition wall 190D. The cover layer 195 may contact a portion of the stress relaxation layer 157 not covered with the touch protective layer 190 in the groove 157R of the stress relaxation layer 157. The cover layer 195 may fill the remaining portion of the groove 157R of the stress relaxation layer 157 that is not filled with the touch protective layer 190. The cover layer 195 may contact at least one of the plurality of partition walls 190D.

According to the present embodiment, the touch protective layer covers the end of the touch insulating layer disposed on the partial area of the stress relaxation layer disposed on the connection line. The touch protective layer as an organic material layer and the stress relaxation layer as an organic material layer contact each other in the groove defined in the upper portion of the stress relaxation layer, so that the adhesive force between the touch protective layer and the stress relaxation layer is improved, thereby preventing the touch insulating layer and the touch buffer layer from being lifted-off from the stress relaxation layer, and preventing moisture from flowing toward the connection lines through a gap between the touch buffer layer and the stress relaxation layer.

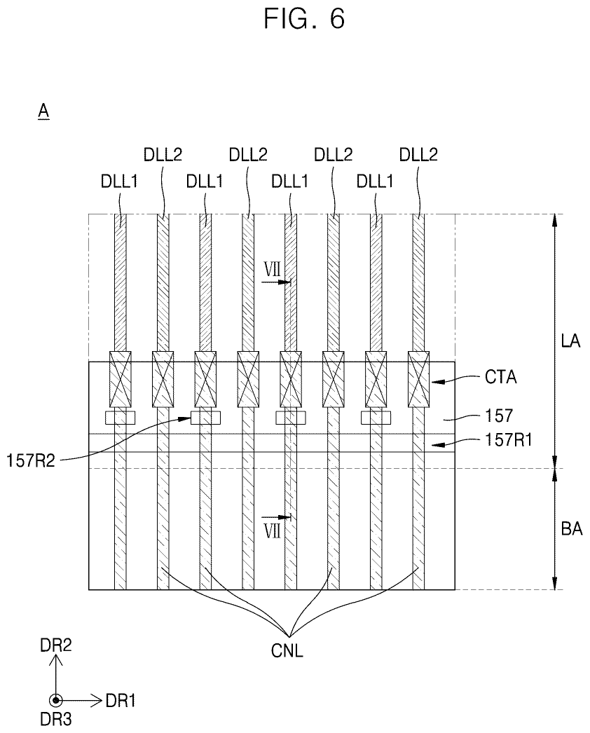

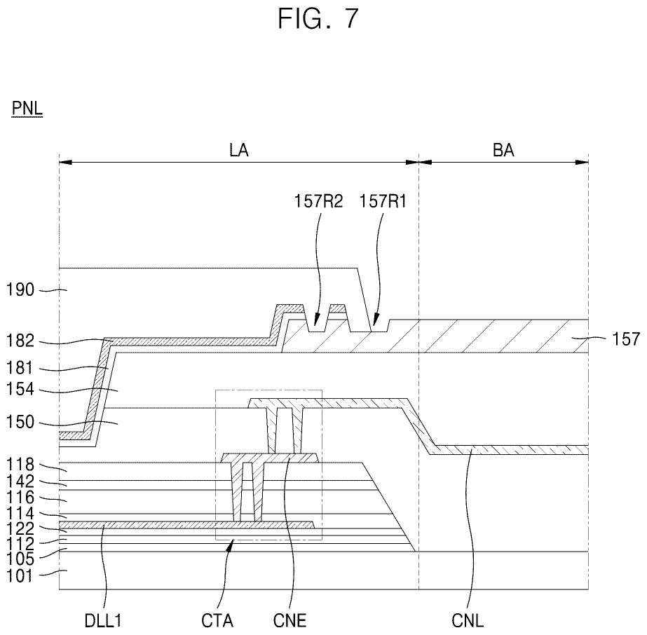

FIG. 6 is a plan view of a display device according to an embodiment of the present disclosure, and is a plan view corresponding to FIG. 3. FIG. 7 is a cross-sectional view taken along a line VII-VII of FIG. 6. In the embodiment of FIGS. 6 and 7, unlike the embodiment of FIGS. 3 and 4, the stress relaxation layer 157 includes a first groove 157R1 and a second groove 157R2 defined therein. Hereinafter, the embodiment of FIGS. 6 and 7 will be mainly described based on differences thereof from the embodiment of FIGS. 3 and 4.

Referring to FIGS. 6 and 7, the stress relaxation layer 157 may include the first groove 157R1 extending in the first direction DR1 so as to intersect the connection lines CNL and at least one second groove 157R2 spaced apart from the first groove 157R in the second direction DR2 intersecting the first direction DR1. The at least one second groove 157R2 may be positioned at a position closer to the display area AA than the first groove 157R1. A spacing between the display area AA and the second groove 157R2 is smaller than a spacing between the display area AA and the first groove 157R1. The at least one second groove 157R2 may be defined at position farther from the bendable area BA than the first groove 157R1. A spacing between the bendable area BA and the second groove 157R2 is larger than a spacing between the bendable area BA and the first groove 157R1. The at least one second groove 157R2 may extend in the first direction DR1. The at least one second groove 157R2 may include a plurality of second grooves 157R2 spaced apart from each other in the first direction DR1. The shape, position, and length of each of the plurality of second grooves 157R2 are not limited to those illustrated in FIG. 5. In an embodiment, the plurality of second grooves 157R2 may be connected to each other to constitute one second groove 157R2. In this case, one second groove 157R2 may extend by the same length as a length by which the first groove 157R1 extends in the first direction DR1. In an embodiment, the plurality of grooves, each extending by the same length as the extension length of the first groove 157R1 may be spaced apart from each other and may be defined in the upper portion of the stress relaxation layer 157. The plurality of grooves spaced apart from each other may be positioned closer to the display area AA than the first groove 157R1.

Each of the touch buffer layer 181 and the touch insulating layer 182 may have at least one opening vertically overlapping and communicating with at least one second groove 157R2. Each of the touch buffer layer 181 and the touch insulating layer 182 may have a plurality of openings vertically overlapping and communicating with the plurality of second grooves 157R2, respectively.

The touch protective layer 190 may fill the at least one opening or the plurality of openings defined in each of the touch buffer layer 181 and the touch insulating layer 182 and vertically overlapping and communicating with the at least one second groove 157R2 or the plurality of second grooves 157R2 of the stress relaxation layer 157. The touch protective layer 190 may contact the stress relaxation layer 157 in the at least one second groove 157R2 or the plurality of second grooves 157R2. The touch protective layer 190 may fill the at least one second groove 157R2 or the plurality of second grooves 157R2 of the stress relaxation layer 157.

An end of the touch protective layer 190 may be located in the first groove 157R of the stress relaxation layer 157R. The touch protective layer 190 may fill a portion of the first groove 157R1 of the stress relaxation layer 157.

According to the present embodiment, a contact area between the touch protective layer as the organic material layer and the stress relaxation layer as the organic material layer is further increased to further improve the adhesion between the touch protective layer and the stress relaxation layer, thereby preventing the touch buffer layer and the touch insulating layer from being lifted-off from the stress relaxation layer, and thus, preventing the moisture from flowing toward the connection lines through the gap between the touch buffer layer and the stress relaxation layer.

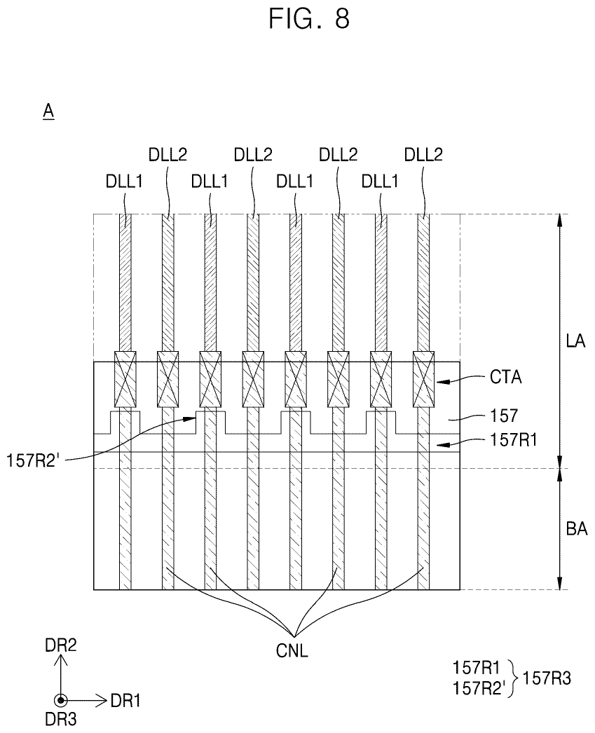

FIG. 8 is a plan view of a display device according to an embodiment of the present disclosure, and is a plan view corresponding to FIG. 3. Unlike the embodiment of FIGS. 6 and 7, in the embodiment of FIG. 8, the stress relaxation layer 157 includes the first groove 157R1 and a second groove 157R2′. Hereinafter, the embodiment of FIG. 8 will be mainly described based on differences from the embodiments of FIGS. 6 and 7.

Referring to FIG. 8, the stress relaxation layer 157 may include the first groove 157R1 extending in the first direction DR1 so as to intersect the connection lines CNL and a plurality of second grooves 157R2′ spaced apart from each other in the first direction DR1. The plurality of second grooves 157R2′ may be positioned closer to the display area AA than the first groove 157R1. The plurality of second grooves 157R2′ may be positioned at a position farther from the bendable area BA than the first groove 157R1. Each of the plurality of second grooves 157R2′ may extend in the first direction DR1. Each of the plurality of second grooves 157R2′ may be connected to the first groove 157R1. The first groove 157R1 and the plurality of second grooves 157R2′ may be connected to each other to constitute one groove 157R3. One groove 157R3 may have one side surface, that is, an inner side surface having a convex-concave pattern, and the other surface, that is, an outer side surface having a linear shape. The shape, position, and length of each of the plurality of second grooves 157R2 are not limited to those illustrated in FIG. 7.

In the present embodiment, the end of each of the touch buffer layer 181 and the touch insulating layer 182 in the link area LA may have a concave-convex pattern. The touch protective layer 190 may cover the end having the concave-convex pattern of each of the touch buffer layer 181 and the touch insulating layer 182. The touch protective layer 190 may be in contact with the stress relaxation layer 157 in the first groove 157R1 and the plurality of second grooves 157R2′ of the stress relaxation layer 157. The end of the touch protective layer 190 may be located in the first groove 157R1 of the stress relaxation layer 157. The touch protective layer 190 may fill a portion of the first groove 157R1 of the stress relaxation layer 157.

According to the present embodiment, the contact area between the touch protective layer and the stress relaxation layer which are respectively the organic material layers, is further increased to further improve the adhesion between the touch protective layer and the stress relaxation layer, thereby preventing the touch buffer layer and the touch insulating layer from being lifted-off from the stress relaxation layer, and thereby preventing moisture from flowing toward the connection lines through the gap between the touch buffer layer and the stress relaxation layer.

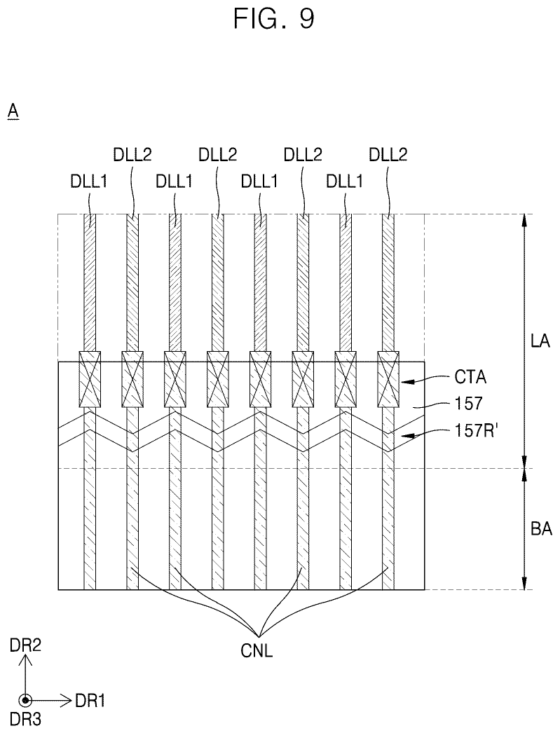

FIG. 9 is a plan view of a display device according to an embodiment of the present disclosure, and is a plan view corresponding to FIG. 3. Unlike the embodiment of FIGS. 3 and 4, in the embodiment of FIG. 9, the stress relaxation layer 157 includes a groove 157R′. Hereinafter, the embodiment of FIG. 9 will be described mainly based on differences thereof from the embodiment of FIGS. 3 and 4.

Referring to FIG. 9, the stress relaxation layer 157 may include the groove 157R′ extending in a zigzag manner in the first direction DR1 intersecting the extension direction of the connection lines CNL in a plan view of the display device.

In the present embodiment, an end of each of the touch buffer layer 181 and the touch insulating layer 182 in the link area LA may have a zigzag shape. An end of the touch protective layer 190 covering the end of each of the touch buffer layer 181 and the touch insulating layer 182 may have a zigzag shape. The touch protective layer 190 may be in contact with the stress relaxation layer 157 in the groove 157R′ of the stress relaxation layer 157. The end of the touch protective layer 190 may be located in the groove 157R′ of the stress relaxation layer 157. The touch protective layer 190 may fill a portion of the groove 157R′ of the stress relaxation layer 157.

According to the present embodiment, the contact area between the touch protective layer and the stress relaxation layer which are respectively organic material layers, is further increased to further improve the adhesion between the touch protective layer and the stress relaxation layer, thereby preventing the touch buffer layer and the touch insulating layer from being lifted-off from the stress relaxation layer, and thereby preventing moisture from flowing toward the connection lines through the gap between the touch buffer layer and the stress relaxation layer.

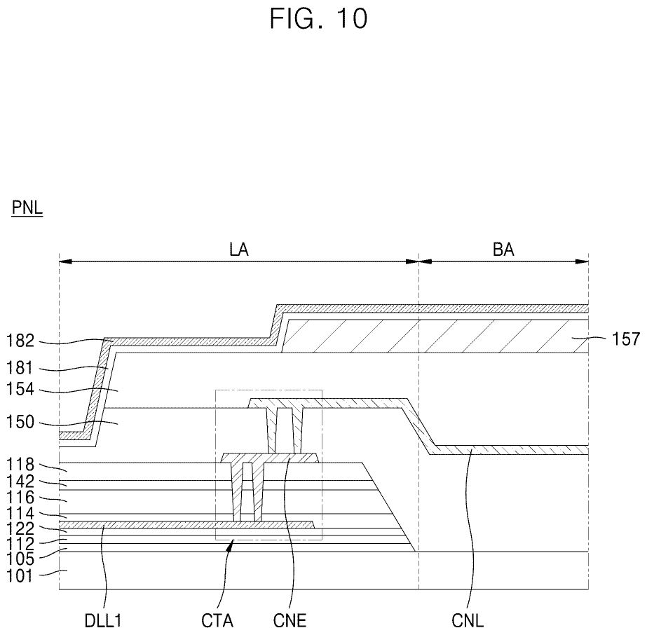

FIGS. 10 to 13 are cross-sectional views illustrating a method for manufacturing a display device according to an embodiment of the present disclosure. Hereinafter, a method for manufacturing a display device according to an embodiment illustrated in FIGS. 3 and 4 will be described.

Referring to FIG. 10, the substrate 101 including the link area LA adjacent to the display area AA and the bendable area BA adjacent to the link area LA is prepared.

Each of the first buffer layer 105, the second buffer layer 112, the first gate insulating layer 122, the first data link line DLL1, the first interlayer insulating layer 114, the isolation insulating layer 116, the second gate insulating layer 142, and the second interlayer insulating layer 118, which are sequentially stacked on the link area LA of the substrate 101, may be formed by deposition and etching processes. An end of the first buffer layer 105 may be located at a boundary between the link area LA and the bendable area BA. An end of the first data link line DLL1 may be covered with the first interlayer insulating layer 114.

Although FIG. 10 illustrates that only the first data link line DLL1 is formed between the first gate insulating layer 122 and the first interlayer insulating layer 114, the second data link line DLL2 may be formed between the first interlayer insulating layer 114 and the isolation insulating layer 116.

The link contact electrode CNE may be formed on the second interlayer insulating layer 118 by deposition and etching processes. The link contact electrode CNE may be connected to the first data link line DLL1 via at least one contact hole extending through the second interlayer insulating layer 118, the second gate insulating layer 142, the isolation insulating layer 116, and the first interlayer insulating layer 114. Before the link contact electrode CNE is formed, the at least one contact hole extending through the second interlayer insulating layer 118, the second gate insulating layer 142, the isolation insulating layer 116, and the first interlayer insulating layer 114 may be pre-formed by an etching process.

The first planarization layer 150 may be formed in the link area LA and the bendable area BA while covering the second interlayer insulating layer 118 and the link contact electrode CNE by coating and photolithography processes.

The connection line CNL may be formed in the link area LA and the bendable area BA and on the first planarization layer 150 by a deposition and etching process. The connection line CNL may be connected to the link contact electrode CNE via at least one contact hole extending through the first planarization layer 150. Before the connection line CNL is formed, the at least one contact hole extending through the first planarization layer 150 may be pre-formed by an etching process.

The second planarization layer 154 may be formed in the link area LA and the bendable area BA while covering the connection line CNL by coating and photolithography processes. The second planarization layer 154 may not cover a portion of the first planarization layer 150 in the link area LA.

The stress relaxation layer 157 may be formed in the link area LA and the bendable area BA and on the second planarization layer 154 by coating and photolithography processes. The stress relaxation layer 157 may not cover a portion of the second planarization layer 154 in the link area LA.

The touch buffer layer 181 and the touch insulating layer 182 may be sequentially formed on the first planarization layer 150, the second planarization layer 154, and the stress relaxation layer 157 by a deposition process.

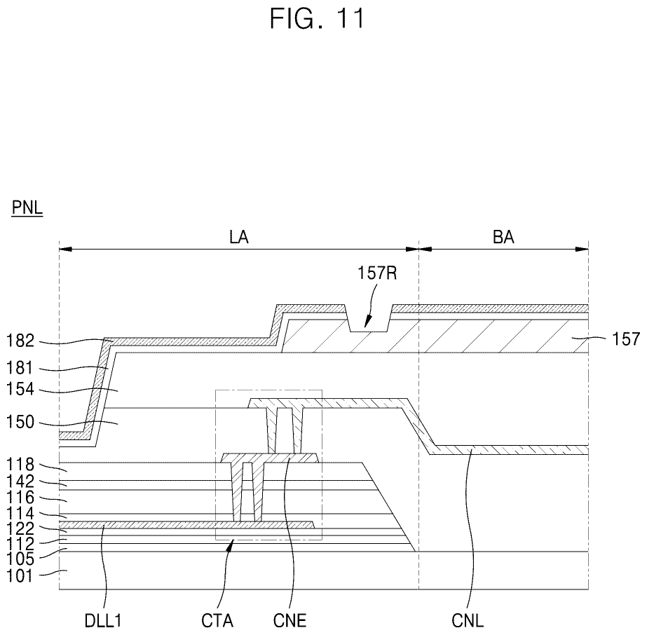

Referring to FIG. 11, by a photolithography process and an etching process, a portion of each of the touch buffer layer 181 and the touch insulating layer 182 may be removed to form an opening extending through the touch buffer layer 181 and the touch insulating layer 182, and the groove 157R vertically overlapping and communicating with the opening defined in the touch buffer layer 181 and the touch insulating layer 182 may be formed in an upper portion of the stress relaxation layer 157. Each of the opening and the groove 157R may extend in a linear shape in a direction so as to intersect the connection line CNL. The etching process may include a dry etching process.

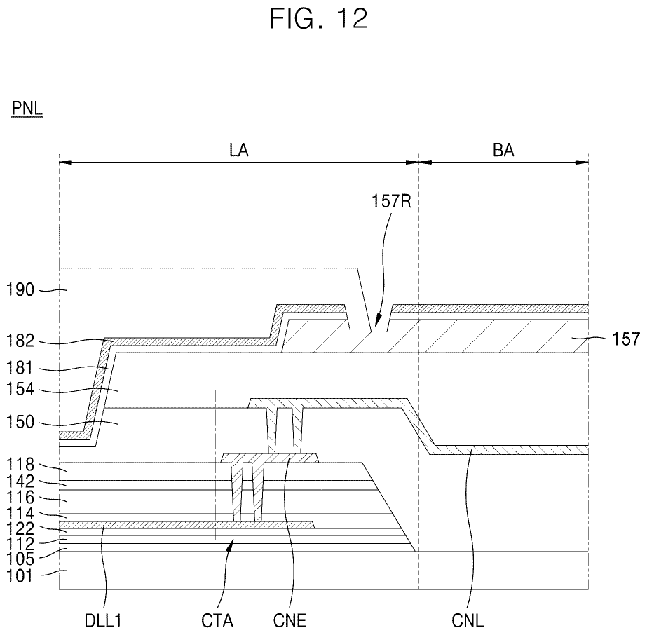

Referring to FIG. 12, a photosensitive organic insulating material may be coated on the touch insulating layer 182, and then a photolithography process may be performed thereon to form the touch protective layer 190 on the touch insulating layer 182. The end of the touch protective layer 190 may be located in the groove 157R of the stress relaxation layer 157. The touch protective layer 190 may cover the end of the touch insulating layer 182 and may be in contact with the stress relaxation layer 157 in the groove 157R of the stress relaxation layer 157. Since the touch protective layer 190 as an organic material layer and the stress relaxation layer 157 as an organic material layer are in contact with each other to improve the adhesion between the touch protective layer 190 and the stress relaxation layer 157, the touch buffer layer 181 and the touch insulating layer 182 may be prevented from being lifted-off from the stress relaxation layer 157. Since the touch insulating layer 182 covers the stress relaxation layer 157 in the bendable area BA, tetramethylammonium hydroxide (TMAH) as a residual component of a developer for patterning the touch protective layer 190 may be prevented from flowing toward the connection line CNL.

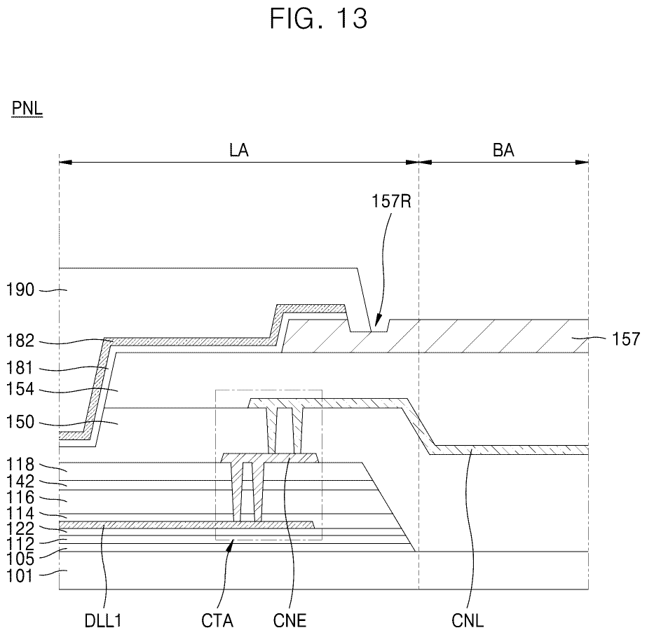

Referring to FIG. 13, a portion of each of the touch buffer layer 181 and the touch insulating layer 182 that is not covered with the touch protective layer 190 may be removed. When the portion of each of the touch buffer layer 181 and the touch insulating layer 182 has been removed, TMAH (tetramethylammonium hydroxide) as a residual component of the developer may also be removed.

According to the manufacturing method of the present embodiment, the touch protective layer and the stress relaxation layer which are respectively the organic material layers may contact each other such that the adhesive force between the touch protective layer and the stress relaxation layer is improved. Thus, the touch buffer layer and the touch insulating layer may be prevented from being lifted-off from the stress relaxation layer. In addition, since the touch buffer layer and the touch insulating layer are partially removed after the patterning of the touch protective layer, corrosion and cracks of the connection lines due to residual components of the developer used in the process for forming the touch protective layer may be prevented.

In a method for manufacturing the display device according to the embodiment as illustrated in FIGS. 6 and 7, only the photolithography process is changed in the process as described above with reference to FIG. 11 while the remaining processes are performed in the same manner as described above.

By a photolithography process and an etching process, a portion of each of the touch buffer layer 181 and the touch insulating layer 182 may be removed to form a first opening extending through the touch buffer layer 181 and the touch insulating layer 182. The first groove 157R1 vertically overlapping and communicating with the first opening defined in the touch buffer layer 181 and the touch insulating layer 182 may be formed in an upper portion of the stress relaxation layer 157. In addition, at least one second opening extending through the touch buffer layer 181 and the touch insulating layer 182 may be formed at a position spaced apart from the first opening and closer to the display area AA than the first opening. Further, at least one second groove 157R2 vertically overlapping and communicating with the at least one second opening may be further formed in the stress relaxation layer 157. The at least one second opening may include a plurality of second openings spaced apart from each other in a direction intersecting the extension direction of the connection line CNL. The at least one second groove 157R2 may include a plurality of second grooves 157R2 spaced apart from each other in a direction intersecting then extension direction of the connection line CNL.

In a method for manufacturing the display device according to the embodiment illustrated in FIG. 8, only the photolithography process is changed in the process as described above with reference to FIG. 11, while the remaining processes are performed in the same manner as described above.

By a photolithography process and an etching process, a portion of each of the touch buffer layer 181 and the touch insulating layer 182 may be removed to form a first opening extending through the touch buffer layer 181 and the touch insulating layer 182. The first groove 157R1 vertically overlapping and communicating with the first opening defined in the touch buffer layer 181 and the touch insulating layer 182 may be formed in an upper portion of the stress relaxation layer 157. In addition, a plurality of second openings connected to the first opening and extending through the touch buffer layer 181 and the touch insulating layer 182 may be formed at a position closer to the display area AA than the first opening. The plurality of second grooves 157R2′ connected to the first groove 157R1 and vertically overlapping and respectively communicating with the plurality of second openings may be further formed in the upper portion of the stress relaxation layer 157. The plurality of second openings may be spaced apart from each other in a direction intersecting the extension direction of the connection line CNL. The plurality of second grooves 157R2 may be spaced apart from each other in a direction intersecting the extension direction of the connection line CNL.

In a method for manufacturing the display device according to the embodiment illustrated in FIG. 9, only the photolithography process is changed in the process as described above with reference to FIG. 11, while the remaining processes are performed in the same manner as described above.

By a photolithography process and an etching process, a portion of each of the touch buffer layer 181 and the touch insulating layer 182 may be removed so as to form the opening extending in the zigzag manner in the plan view and extending through the touch buffer layer 181 and the touch insulating layer 182 in the cross-sectional view. Then, the groove 157R′ vertically overlapping and communicating with the opening defined in the touch buffer layer 181 and the touch insulating layer 182 may be formed in an upper portion of the stress relaxation layer 157. The groove 157R′ extends in the zigzag manner in the plan view.

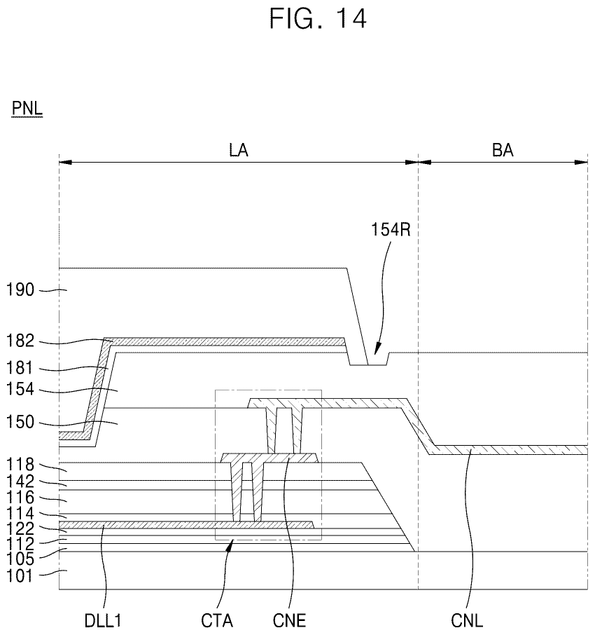

FIG. 14 is a cross-sectional view of a display device according to an embodiment of the present disclosure. Unlike the embodiment of FIG. 4, the display device according to the embodiment of FIG. 14 may not include the stress relaxation layer 157 in the link area LA and the bendable area BA.

Referring to FIG. 14, the touch buffer layer 181 and the touch insulating layer 182 may be disposed on the second planarization layer 154 in the link area LA of the non-display area NAA. A groove 154R extending so as to intersect the connection lines CNL may be defined in an upper portion of the second planarization layer 154.

The touch buffer layer 181 and the touch insulating layer 182 may extend from the display area AA and cover a portion of the upper surface of the second planarization layer 154 in the link area LA. An end of the touch buffer layer 181 and an end of the touch insulating layer 182 may be aligned with each other. The groove 154R defined in the second planarization layer 154 may be adjacent to an end of the touch buffer layer 181 and an end of the touch insulating layer 182. A side surface of the end of the touch buffer layer 181 may be aligned with an inner side surface of the groove 154R of the second planarization layer 154. The inner surface of the groove 154R of the second planarization layer 154 is a side surface closer to the display area AA among opposite side surfaces of the groove 154R of the second planarization layer 154, and an outer side surface of the groove 154R of the second planarization layer 154 is a side surface closer to the bendable area BA among the opposite side surfaces of the groove 154R of the second planarization layer 154.

The touch protective layer 190 may be disposed on the touch insulating layer 182. The touch protective layer 190 may cover the end of the touch buffer layer 181 and the end of the touch insulating layer 182. The touch protective layer 190 may be in contact with the second planarization layer 154 in the groove 154R of the second planarization layer 154. The end of the touch protective layer 190 may be located in the groove 154R of the second planarization layer 154. The touch protective layer 190 may fill a portion of the groove 154R of the second planarization layer 154.

According to the present embodiment, the touch protective layer covers the end of the touch insulating layer disposed on a partial area of the second planarization layer disposed on the connection line. The touch protective layer and the second planarization layer which are respectively organic material layers are brought into contact with each other in the groove of the second planarization layer, so that the adhesive force between the touch protective layer and the second planarization layer is improved, thereby preventing the touch insulating layer and the touch buffer layer from being lifted-off from the second planarization layer, and thereby preventing moisture from flowing toward the connection lines through a gap between the touch buffer layer and the second planarization layer.

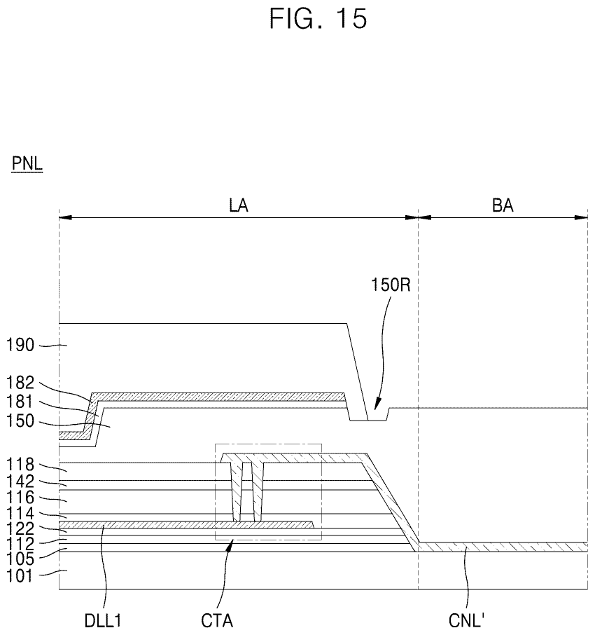

FIG. 15 is a cross-sectional view of a display device according to an embodiment of the present disclosure. Unlike the embodiment of FIG. 4, the display device according to the embodiment of FIG. 14 may not include the second planarization layer 154 and the stress relaxation layer 157 in the link area LA and the bendable area BA.

Referring to FIG. 15, a connection line CNL′ may be disposed on the upper surface of the second interlayer insulating layer 118 in the link area LA, and may be disposed on the upper surface of the substrate 101 in the bendable area BA. The connection line CNL′ may cover an end of each of the first interlayer insulating layer 114, the isolation insulating layer 116, the second gate insulating layer 142, and the second interlayer insulating layer 118, and may extend to the bendable area BA. The connection line CNL′ may be connected to the first data link line DLL1 via a contact hole extending through the first interlayer insulating layer 114, the isolation insulating layer 116, the second gate insulating layer 142, and the second interlayer insulating layer 118 in the contact area CTA.

The first planarization layer 150 may be disposed on the connection line CNL′ and in the link area LA and the bendable area BA.

The touch buffer layer 181 and the touch insulating layer 182 may be disposed on the first planarization layer 150 and in the link area LA of the non-display area NAA. A groove 150R extending so as to intersect the connection lines CNL may be defined in the first planarization layer 150.

The touch buffer layer 181 and the touch insulating layer 182 may extend from the display area AA and cover a portion of the upper surface of the first planarization layer 150 in the link area LA. An end of the touch buffer layer 181 and an end of the touch insulating layer 182 may be aligned with each other. A groove 150R of the first planarization layer 150 may be positioned adjacent to an end of the touch buffer layer 181 and an end of the touch insulating layer 182. A side surface of an end of the touch buffer layer 181 may be aligned with an inner side surface of the groove 150R of the first planarization layer 150. The inner side surface of the groove 150R of the first planarization layer 150 is a side surface close to the display area AA among opposite side surfaces of the groove 150R of the first planarization layer 150, and the outer side surface of the groove 150R of the first planarization layer 150 is a side surface close to the bendable area BA among opposite side surfaces of the groove 150R of the first planarization layer 150.

The touch protective layer 190 may be disposed on the touch insulating layer 182. The touch protective layer 190 may cover an end of the touch buffer layer 181 and an end of the touch insulating layer 182. The touch protective layer 190 may be in contact with the first planarization layer 150 in the groove 150R of the first planarization layer 150. An end of the touch protective layer 190 may be located in the groove 150R of the first planarization layer 150. The touch protective layer 190 may fill a portion of the groove 150R of the first planarization layer 150.

According to the present embodiment, the touch protective layer covers the end of the touch insulating layer disposed on the partial area of the first planarization layer disposed on the connection line, and the touch protective layer and the first planarization layer which are respectively organic material layers are in contact with each other in the groove of the first planarization layer, so that an adhesive force between the touch protective layer and the first planarization layer is improved, thereby preventing the touch insulating layer and the touch buffer layer from being lifted-off from the first planarization layer, and preventing moisture from flowing toward the connection lines through a gap between the touch buffer layer and the first planarization layer.

A display device and a manufacturing method thereof according to various aspects and embodiments of the present disclosure may be described as follows.

A first aspect of the present disclosure provides a display device comprising: a substrate including a display area in which a plurality of light-emitting elements are disposed, a link area adjacent to the display area, and a bendable area adjacent to the link area; a signal line disposed on the link area so as to transmit a signal to the display area; a connection line disposed on the signal line and connected to the signal line, wherein the connection line extends from the link area to the bendable area; a planarization layer disposed on the connection line; a stress relaxation layer disposed on a partial area of the planarization layer; at least one inorganic insulating layer disposed on the planarization layer and a partial area of the stress relaxation layer; and an organic protective layer disposed on the at least one inorganic insulating layer and the stress relaxation layer and covering a end of the at least one inorganic insulating layer, wherein a first groove is defined in an upper portion of the stress relaxation layer and is adjacent to a end of the at least one inorganic insulating layer, wherein the organic protective layer is in contact with the stress relaxation layer in the first groove.

In accordance with some embodiments of the first aspect of the present disclosure, a side surface of the end of the at least one inorganic insulating layer is aligned with an inner side surface of the first groove defined in the upper portion of the stress relaxation layer.

In accordance with some embodiments of the first aspect of the present disclosure, a n end of the organic protective layer is located in the first groove.

In accordance with some embodiments of the first aspect of the present disclosure, the first groove intersects the connection line and extends in a linear shape in a plan view of the display device.

In accordance with some embodiments of the first aspect of the present disclosure, the first groove intersects the connection line and extends in a zigzag shape in a plan view of the display device.

In accordance with some embodiments of the first aspect of the present disclosure, at least one second groove is further defined in the upper portion of the stress relaxation layer and is spaced apart from the first groove, wherein the at least one second groove is positioned at a position closer to the display area than the first groove, wherein the organic protective layer is in contact with the stress relaxation layer in the at least one second groove.

In accordance with some embodiments of the first aspect of the present disclosure, the at least one second groove intersects the connection line in a plan view of the display device.

In accordance with some embodiments of the first aspect of the present disclosure, the at least one second groove includes a plurality of second grooves spaced apart from each other in a direction intersecting an extension direction of the connection line in a plan view of the display device.

In accordance with some embodiments of the first aspect of the present disclosure, a plurality of second grooves are further defined in the upper portion of the stress relaxation layer, wherein the plurality of second grooves are positioned at a position closer to the display area than the first groove, wherein the plurality of second grooves are connected to the first groove.

In accordance with some embodiments of the first aspect of the present disclosure, the display device further comprises a plurality of inorganic insulating layers disposed on the link area and disposed under the connection line disposed between two adjacent ones of the plurality of inorganic insulating layers, wherein ends of the plurality of inorganic insulating layers on the link area provide an inclined side surface, wherein the first groove vertically overlaps a portion of the inclined side surface.

In accordance with some embodiments of the first aspect of the present disclosure, the end of the lowest inorganic insulating layer among the plurality of inorganic insulating layers is positioned closer to the bending region than the first groove. A spacing between the bendable area and an end of a lowermost inorganic insulating layer among the plurality of inorganic insulating layers is smaller than a spacing between the bendable area and the first groove.

A second aspect of the present disclosure provides a method for manufacturing a display device, the method comprising: providing a substrate including a display area in which a plurality of light-emitting elements are disposed, a link area adjacent to the display area, and a bendable area adjacent to the link area; forming a signal line on the link area of the substrate; forming a connection line on the signal line so as to extend from the link area of the substrate to the bendable area thereof; forming a planarization layer on the connection line; forming a stress relaxation layer on a partial area of the planarization layer; forming at least one inorganic insulating layer so as to cover the planarization layer and the stress relaxation layer; forming a first opening extending through the at least one inorganic insulating layer and a first groove vertically overlapping the first opening in an upper portion of the stress relaxation layer; forming an organic protective layer so as to cover a portion of the at least one inorganic insulating layer on the link area, wherein an end of the organic protective layer is located in the first groove; and removing a portion of the at least one inorganic insulating layer not covered with the organic protective layer.

In accordance with some embodiments of the second aspect of the present disclosure, each of the first opening and the first groove intersects the connection line and extends in a linear shape in a plan view of the display device.

In accordance with some embodiments of the second aspect of the present disclosure, each of the first opening and the first groove intersects the connection line and extends in a zigzag shape in a plan view of the display device.

In accordance with some embodiments of the second aspect of the present disclosure, the forming of the first opening and the first groove further includes: forming at least one second opening extending through the at least one inorganic insulating layer at a position spaced apart from the first opening; and forming at least one second groove vertically overlapping the first opening in the upper portion of the stress relaxation layer.

In accordance with some embodiments of the second aspect of the present disclosure, the forming of the first opening and the first groove further includes: forming a plurality of second openings extending through the at least one inorganic insulating layer and being connected to the first opening; and forming a plurality of second grooves vertically overlapping the plurality of second openings respectively and being connected to the first groove.

A third aspect of the present disclosure provides a display device comprising: a substrate including a display area in which a plurality of light-emitting elements are disposed, a link area adjacent to the display area, and a bendable area adjacent to the link area; a signal line disposed on the link area so as to transmit a signal to the display area; a connection line disposed on the signal line and connected to the signal line, wherein the connection line extends from the link area to the bendable area; a planarization layer disposed on the connection line; at least one inorganic insulating layer disposed on a partial area of the planarization layer; and an organic protective layer disposed on the at least one inorganic insulating layer so as to cover an end of the at least one inorganic insulating layer, wherein a groove is defined in an upper portion of the planarization layer and is adjacent to an end of the at least one inorganic insulating layer, wherein the organic protective layer is in contact with the planarization layer in the groove.

In accordance with some embodiments of the third aspect of the present disclosure, the display device further comprises a plurality of inorganic insulating layers disposed on the link area and disposed under the connection line, wherein the signal line is disposed between two adjacent ones of the plurality of inorganic insulating layers, wherein ends of the plurality of inorganic insulating layers on the link area provide an inclined side surface, wherein the groove vertically overlaps a portion of the inclined side surface.

In accordance with some embodiments of the third aspect of the present disclosure, the end of the lowest inorganic insulating layer among the plurality of inorganic insulating layers is positioned closer to the bending region than the first groove. A spacing between the bendable area and an end of a lowermost inorganic insulating layer among the plurality of inorganic insulating layers is smaller than a spacing between the bendable area and the groove.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a substrate including a display area in which a plurality of light-emitting elements are disposed, a link area adjacent to the display area, and a bendable area adjacent to the link area;
a signal line disposed on the link area to transmit a signal to the display area;
a connection line disposed on the signal line and connected to the signal line, wherein the connection line extends from the link area to the bendable area;
a planarization layer disposed on the connection line;
a stress relaxation layer disposed on a partial area of the planarization layer;
at least one inorganic insulating layer disposed on the planarization layer and a partial area of the stress relaxation layer; and
an organic protective layer disposed on the at least one inorganic insulating layer and the stress relaxation layer and covering an end of the at least one inorganic insulating layer,
wherein a first groove is defined in an upper portion of the stress relaxation layer and is adjacent to the end of the at least one inorganic insulating layer, and
wherein the organic protective layer is in contact with the stress relaxation layer in the first groove.

2. The display device of claim 1, wherein a side surface of the end of the at least one inorganic insulating layer is aligned with an inner side surface of the first groove defined in the stress relaxation layer.

3. The display device of claim 1, wherein an end of the organic protective layer is located in the first groove.

4. The display device of claim 1, wherein the first groove intersect the connection line and extends in a linear shape in a plan view of the display device.

5. The display device of claim 1, wherein the first groove intersect the connection line and extends in a zigzag shape in a plan view of the display device.

6. The display device of claim 1, wherein at least one second groove is further defined in the upper portion of the stress relaxation layer and is spaced apart from the first groove, wherein the at least one second groove is positioned at a position closer to the display area than the first groove,
wherein the organic protective layer is in contact with the stress relaxation layer in the at least one second groove.

7. The display device of claim 6, wherein the at least one second groove intersects the connection line in a plan view of the display device.

8. The display device of claim 6, wherein the at least one second groove includes a plurality of second grooves spaced apart from each other in a direction intersecting an extension direction of the connection line in a plan view of the display device.

9. The display device of claim 1, wherein a plurality of second grooves are further defined in the upper portion of the stress relaxation layer, wherein the plurality of second grooves are positioned at a position closer to the display area than the first groove, and
wherein the plurality of second grooves are connected to the first groove.

10. The display device of claim 1, wherein the display device further comprises a plurality of inorganic insulating layers disposed on the link area and disposed under the connection line,
wherein the signal line is disposed between two adjacent ones of the plurality of inorganic insulating layers,
wherein ends of the plurality of inorganic insulating layers on the link area provide an inclined side surface,
wherein the first groove vertically overlaps a portion of the inclined side surface.

11. The display device of claim 10, wherein the end of the lowest inorganic insulating layer among the plurality of inorganic insulating layers is positioned closer to the bending region than the first groove.

12. A method for manufacturing a display device, the method comprising:
providing a substrate including a display area in which a plurality of light-emitting elements are disposed, a link area adjacent to the display area, and a bendable area adjacent to the link area;
forming a signal line on the link area of the substrate;
forming a connection line on the signal line so as to extend from the link area of the substrate to the bendable area thereof;
forming a planarization layer on the connection line;
forming a stress relaxation layer on a partial area of the planarization layer;
forming at least one inorganic insulating layer so as to cover the planarization layer and the stress relaxation layer;
forming a first opening extending through the at least one inorganic insulating layer and a first groove vertically overlapping the first opening in an upper portion of the stress relaxation layer;
forming an organic protective layer to cover a portion of the at least one inorganic insulating layer on the link area, wherein an end of the organic protective layer is located in the first groove; and
removing a portion of the at least one inorganic insulating layer not covered with the organic protective layer.

13. The method for manufacturing the display device of claim 12, wherein each of the first opening and the first groove intersects the connection line and extends in a linear shape in a plan view of the display device.

14. The method for manufacturing the display device of claim 12, wherein each of the first opening and the first groove intersects the connection line and extends in a zigzag shape in a plan view of the display device.

15. The method for manufacturing the display device of claim 12, wherein the forming of the first opening and the first groove further includes:
forming at least one second opening extending through the at least one inorganic insulating layer at a position spaced apart from the first opening, and at least one second groove vertically overlapping the first opening in the upper portion of the stress relaxation layer.

16. The method for manufacturing the display device of claim 12, wherein the forming of the first opening and the first groove further includes:
forming a plurality of second openings extending through the at least one inorganic insulating layer and being connected to the first opening, and a plurality of second grooves vertically overlapping the plurality of second openings respectively and being connected to the first groove.

17. A display device comprising:
a substrate including a display area in which a plurality of light-emitting elements are disposed, a link area adjacent to the display area, and a bendable area adjacent to the link area;
a signal line disposed on the link area to transmit a signal to the display area;
a connection line disposed on the signal line and connected to the signal line, wherein the connection line extends from the link area to the bendable area;
a planarization layer disposed on the connection line;
at least one inorganic insulating layer disposed on a partial area of the planarization layer; and
an organic protective layer disposed on the at least one inorganic insulating layer so as to cover an end of the at least one inorganic insulating layer,
wherein a groove is defined in an upper portion of the planarization layer and is adjacent to an end of the at least one inorganic insulating layer, and
wherein the organic protective layer is in contact with the planarization layer in the groove.

18. The display device of claim 17, wherein the display device further comprises a plurality of inorganic insulating layers disposed on the link area and disposed under the connection line,
wherein the signal line is disposed between two adjacent ones of the plurality of inorganic insulating layers,
wherein ends of the plurality of inorganic insulating layers on the link area provide an inclined side surface, and
wherein the groove vertically overlaps a portion of the inclined side surface.

19. The display device of claim 18, wherein the end of the lowest inorganic insulating layer among the plurality of inorganic insulating layers is positioned closer to the bending region than the first groove.
